(19) United States
(12) Patent Application Publication
(10) Pub. No.: US 2005/0243881 A1
(43) Pub. Date: Nov. 3, 2005

(54) InAlAs having enhanced oxidation rate grown under very low V/III ratio

(76) Inventors: Hoki Kwon, Plymouth, MN (US); Tzu-Yu Wang, Maple Grove, MN (US); Jae-Hyun Ryou, Maple Grove, MN (US); Jin K. Kim, St. Louis Park, MN (US); Gyoungwon Park, Allentown, PA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/026,397

(22) Filed: Dec. 30, 2004

Related U.S. Application Data
(60) Provisional application No. 60/566,743, filed on Apr. 30, 2004.

(51) Int. Cl. H01S 5/00

(52) U.S. Cl. 372/46.01; 372/98; 372/45.01

(57) ABSTRACT

A current confinement layer of a VCSEL is formed by adjusting flow rates of In-, Al-, and As-containing precursors introduced within a deposition chamber. By maintaining a low ratio between the flow rate of the As-containing precursors and the total flow rate of In- and Al-containing precursors (e.g., less than 25, 10, 5, or 1), a current confinement layer, lattice matched to InP and having an enhanced oxidation rate, may be formed.

### CROSS-REFERENCE TO RELATED APPLICATIONS

This application claims the benefit of U.S. Provisional Application No. 60/566,743, filed Apr. 30, 2004 and entitled InAlAs HAVING ENHANCED OXIDATION RATE GROWN UNDER VERY LOW V/III RATIO, which is hereby incorporated by reference.

### BACKGROUND OF THE INVENTION

1. Field of the Invention

The present invention relates to vertical cavity surface emitting lasers (VCSELs). More particularly, the invention relates to current confinement layers used in VCSELs, and methods of fabricating the same.

2. Field of the Invention

Vertical cavity surface emitting lasers (VCSELs) represent a relatively new class of semiconductor laser. While there are many variations of VCSELs, one common characteristic is that they emit light perpendicular to a substrate's surface. Advantageously, VCSELs can be formed from a wide range of material systems to produce coherent light at different wavelengths, e.g., 1550 nm, 1310 nm, 850 nm, 670 nm, etc.

VCSELs include semiconductor active regions, distributed Bragg reflector (DBR) mirrors, current confinement layers, substrates, and contacts. Because of their complicated structure, and because of their material requirements, VCSELs are usually grown using metal-organic chemical vapor deposition (MOCVD) or molecular beam epitaxy (MBE).

FIG. 1 illustrates a typical VCSEL 10. As shown, an n-doped gallium arsenide (GaAs) substrate 12 has an n-type electrical contact 14. An n-doped lower mirror stack (including a DBR) 16 is formed on the GaAs substrate, and an n-type graded-index lower spacer 18 is disposed over the lower mirror stack 16. An active region 20, usually having a number of quantum wells, is formed over the lower spacer 18. A p-type graded index top spacer 22 is disposed over the active region20, and a p-type top mirror stack (including another DBR) 24 is disposed over the top spacer 22. Over the top mirror stack 24 is a p-type conduction layer 9, a p-type cap layer 8, and a p-type electrical contact 26.

Still referring to FIG. 1, the lower spacer 18 and the top spacer 22 separate the lower mirror stack 16 from the top mirror stack 24 such that an optical cavity is formed. As the optical cavity is resonant at specific wavelengths, the distance between the mirror stacks is controlled to be resonant at a predetermined wavelength (or at multiples thereof). At least part of the top mirror stack includes a current confinement layer 40, which is an electrically insulative region that provides current confinement. The current confinement layer 40 can be formed by forming an oxide layer beneath the top mirror stack 24 to define a conductive annular opening 42 which confines electrical current flow to the active region 20 and eliminates transverse mode lasing. Generally, the current confinement layer 40 is formed by exposing a high aluminum content Group III-V semiconductor material (e.g., Alₓ,Ga₍₁₋ₓ₎ As) to a water containing environment and a temperature of at least 375 ° C., thereby converting at least a portion of the aluminum bearing semiconductor material to a native oxide.

In operation, an electrical bias causes an electrical current 21 to flow from the p-type electrical contact 26 toward the n-type electrical contact 14. The current confinement layer 40 and the conductive opening 42 confine the current 21 such that the current flows through the conductive opening 42 and into the active region 20. Some of the electrons in the current 21 are converted into photons in the active region 20. Those photons bounce back and forth (resonate) between the lower and top mirror stacks 16 and 24. While the lower and top mirror stacks 16 and 24 are very good reflectors, some photons leak out as light 23 that travels along an optical path through the p-type conduction layer 9, through the p-type cap layer 8, through an aperture 30 in the p-type electrical contact 26, and out of the surface of the VCSEL 10.

It should be understood that the VCSEL 10 illustrated in FIG. 1 is a typical device, and that numerous variations are possible. For example, dopings can be changed (e.g., by providing a p-type substrate), different material systems can be used, operational details can be tuned for maximum performance, and additional structures, such as tunnel junctions, can be added.

While generally successful, VCSELs such as those illustrated in FIG. 1 are not without their problems. For example, a major problem in realizing commercial quality VCSELs capable of lasing at long wavelengths of 1310 nm, 1550 nm, etc., relates to the materials used in forming the current confinement layer 40. For example, current confinement layer 40, including high aluminum content Group III-V semiconductor materials (e.g., Alₓ,Ga₍₁₋ₓ₎As, etc.), are lattice matched to GaAs material systems. Lattices are often matched to avoid introducing strain into the VCSEL structure that might reduce the reliability of the device. GaAs material systems are often used in VCSELs capable of emitting at wavelengths of 850 nm and below and are thus of little commercial value in the telecommunications industry which operates at long wavelengths of 1310 nm, 1550 nm, etc. Therefore, long-wavelength VCSELs are often based on InP material systems. However, there is no “x” value for which AlₓGa₍₁₋ₓ₎As is suitably lattice matched to InP. Aluminum containing semiconductor material such as Al_{y}In_{(1-y)}As is lattice matched to InP where “y” is about 0.5. However, at such low aluminum content, the InAlAs material oxidizes too slowly (i.e., ˜1μm/hour @ 500° C.) to be economically used in forming the current confinement layer 40.

It is generally understood that the current confinement layer 40 is oxidized via a substitutional process whereby oxygen is substituted for a Group V element within the semiconductor material (e.g., As is substituted for O, wherein In_{(1-y)}Al_{y}As→In_{(1-y)} Al_{y}O). As “y” increases, the oxidation rate of In_{(1-y)}Al_{y}As also increases. Undesirably, however, increases in “y” are also accompanied by excessive amounts of strain and dislocations within adjacent layers. AlAsSb, another aluminum containing Group III-V semiconductor material lattice-matched to InP, oxidizes quickly at low temperatures but deleteriously decomposes into metallic Sb as it oxidizes and forms interfacial layers that lead to increased strain in the oxidized structure, thus reducing the reliability of the VCSEL device.

To overcome the aforementioned limitations of ternary AlInAs and AlAsSb materials that are compatible with InP-based material systems, AlGaAsSb-based materials with a high refractive index contrasts similar to AlGaAs-based systems and relatively fast oxidation rates have been closely examined. However, the accuracy and reproducibility of an As/Sb composition in an AlGaAsSb system is very difficult to achieve during conventional layer fabrication. Moreover, while AlPSb-based materials may oxide quickly, they too are difficult to grow.

Thus, new long wavelength VCSELs would be beneficial. Even more benefical would be a new method to fast oxidizing current confinement layers that are compatible with the InP material system.

### BRIEF SUMMARY OF THE INVENTION

Accordingly, the present invention is directed to InAlAs grown under very low V/III ratio having enhanced oxidation rate that substantially obviates one or more of the problems due to limitations and disadvantages of the related art.

An advantage of the present invention provides a material used in forming current confinement structures that is lattice-matched to INP material systems.

Another advantage of the present invention provides a material used in forming current confinement structures that has a relatively fast oxidation rate.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, a method of fabricating aluminum containing semiconductor layers may, for example, include locating a substrate in a deposition chamber; setting a temperature of the deposition chamber to deposition temperature; introducing group V-containing precursors into the deposition chamber at a first flow rate and introducing group III-containing precursors into the deposition chamber at a second flow rate, thereby forming an aluminum containing semiconductor layer, wherein a ratio of the first flow rate to the second flow rate is less than 25.

In another aspect of the present invention, a method of fabricating a vertical cavity surface emitting laser (VCSEL) may, for example, include providing an active region; forming an aluminum containing current confinement layer over the active redion; oxidizing a portion the current confinement layer to form a central aperture; and forming a distributed Bragg reflector (DBR) over the active region, wherein forming the aluminum containing current confinement layer includes introducing, at a deposition temperature, group V-containing precursors and group III-containing precursors into a deposition chamber at a second flow rate, wherein a ratio of the first flow rate to the second flow rate is less than 25.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description explain the principles of the invention.

In the drawings:

FIG. 1 illustrates a typical vertical cavity surface emitting laser (VCSEL); and

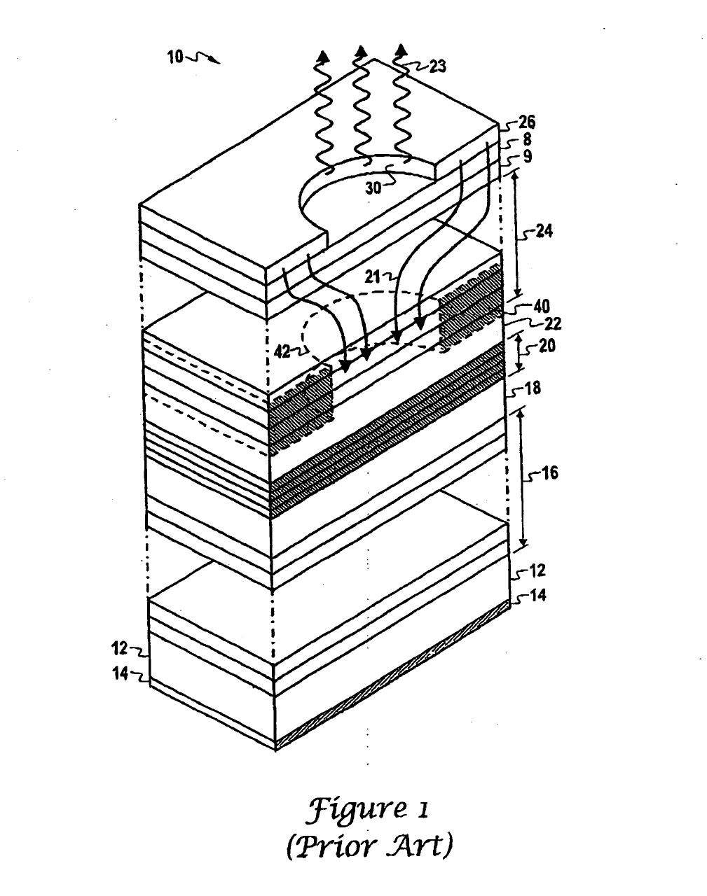

FIG. 2 illustrates an exemplary vertical cavity surface emitting laser (VCSEL) including a current confinement layer in according with the principles of the present invention.

### DETAILED DESCRIPTION OF THE ILLUSTRATED EMBODIMENTS

Reference will now be made in detail to embodiments of the present invention, examples of which are illustrated in the accompanying drawings.

As mentioned above, while complex ternary and even quatemary compounds may be desirable or even necessary as oxidation layers within InP systems, they can be difficult to grow. The principles of the present invention exploit the relative ease with which InAlAs compounds can be grown while enhancing the ability with which such compounds can be oxidized.

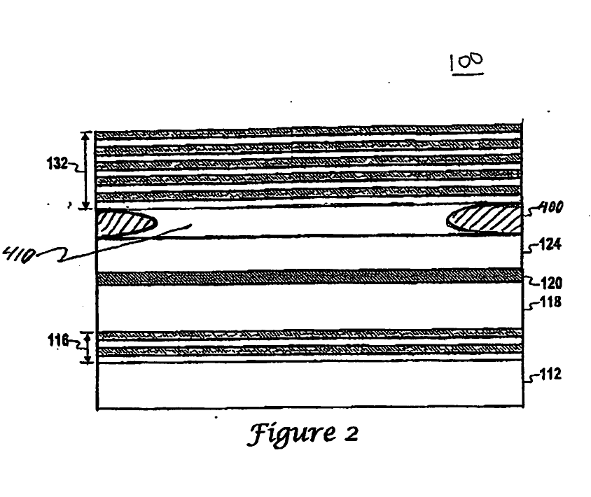

FIG. 2 illustrates an exemplary vertical cavity surface emitting laser including a current confinement layer in accordance with the principles of the present invention.

As shown in FIG. 2, an exemplary long-wavelength VCSEL 100 may, for example, include in n-doped InP substrate 112 having an n-type electrical contact (not shown for clarity). Over the InP substrate 112 may include an n-doped lower mirror stack 116 (including a DBR) comprised of a plurality of alternating layers of AlGaInAs/AlInAs. Over the lower mirror stack 116 is an n-doped InP spacer 118. The lower mirror stack 116 may be beneficially grown on the InP substrate using common metal-organic and hydride precursors such as TMA1, TMGa, PH₃, and AsH₃ in a metal-organic chemical vapor deposition (MOCVD) process. Next, an InP spacer 118 may be grown, also using MOCVD processes. An active region 120 comprised of P-N junction structures and having a large number of quantum wells is then formed over the InP spacer 118. The composition of the active region 120 is beneficially InGaAsP or AlInGaAs.

An n-type InP top spacer 124 may be formed over the active region 120. Subsequently, the current confinement layer 400 may, for example, be formed over the InP top spacer 124 and partially oxidized, as will be discussed in greater detail below. Next, an n-type top mirror stack (which may include another DBR) 132 may be disposed over the current confinement layer 400. In one aspect of the present invention, the top mirror stack 132 may, for example, include alternating layers of materials having high and low indicies of refraction (e.g., AlGaAs, InGaP, InGaAsP, etc.).

According to principles of the present invention, the current confinement layer 400 may, for example, be formed by arranging VCSEL device formed with the InP top spacer 124 into a deposition chamber and introducing In-, Al-, and As-containing precursors into the deposition chamber and maintaining the vapor pressures of each of the precursors in a predetermined manner. During formation of the current confinement layer 400, the vapor pressures of each of the precursors may be controlled by controlling the flow rates of the precursors within the deposition chamber. In one aspect of the present invention, the current confinement layer 400 may be formed while maintaining a low ratio between the flow rate of the As-containing precursors (i.e., the Group V-containing precursors) and the total flow rate of In- and Al-containing precursors (i.e., the Group III-containing precursors). Such a V/III ratio may be, for example, less than 25 (e.g., less than about 10, less than about 5, or even less than about 1).

In one aspect of the present invention, As-containing precursors may, for example, include AsH₃. In another aspect of the present invention, In-containing precursors may, for example, include TMIn. In still another aspect of the present invention, Al-containing precursors may, for example, include TMAl. In yet another aspect of the present invention, the temperature at which the current confinement layer 400 is formed may be higher than about 600° C. (e.g., higher than about 650° C., or even higher than about 700° C.). In a further aspect of the present invention, the current confinement layer may be between about 500Å and about 5000Åthick. As will be understood, substantially any suitable deposition method may be employed to form the current confinement layer 400 (e.g., MOCVD, MBE, CVD, etc.).

After forming the top mirror stack 132, the current confinement layer 400 may be oxidized by any suitable means to form an isolating ring around a central aperture 410. The size of the central aperture 410 may be controlled by adjusting the time during which the current confinement layer 400 is oxidized. Accordingly, the central aperture 410 may serve as the electrical current pathway, enabling the VCSEL 100 to be electrically pumped. Besides providing the electrical current pathway, the current confinement layer 400 may also provide strong index guiding to the optical mode of the VCSEL 100.

It is contemplated that the material quality of the current confinement layer 400 (e.g., surface morphology, crystal quality, impurity concentration, etc.) may become degraded as the deposition temperature increases and/or as the V/III ratio decreases. Thus, when forming the current confinement layer 400, consideration should be given to the minimum material quality the layer is to have in order to achieve a maximum desirable oxidation rate. It will be readily understood that the principles of the present invention may be extended to the formation of other oxidizable Al-containing semiconductor materials such as AlGaAs, AlAsSb, AlGaP, AlInP, AlInSb, etc.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A vertical cavity surface emitting laser (VCSEL), comprising:
an active region;
a distributed Bragg reflector (DBR) arranged over the active region; and
a current confinement layer between the active region and the DBR,
wherein the current confinement layer includes an aluminum containing V/III semiconductor material formed by introducing group V-containing precursors into a deposition chamber at a first flow rate and introducing group III-containing precursors into the deposition chamber at a second flow rate, wherein a ratio of the first flow rate to the second flow rate is less than 25.

2. The VCSEL according to claim 1, wherein the aluminum containing V/III semiconductor material is deposited at deposition temperature of greater than about 600° C.

3. The VCSEL according to claim 2, wherein the deposition temperature is greater than about 650° C.

4. The VCSEL according to claim 2, wherein the deposition temperature is greater than about 700° C.

5. The VCSEL according to claim 1, wherein the a ratio of the first flow rate to the second flow rate is less than 10.

6. The VCSEL according to claim 1, wherein the a ratio of the first flow rate to the second flow rate is less than 5.

7. The VCSEL according to claim 1, wherein the a ratio of the first flow rate to the second flow rate is less than 1.

8. The VCSEL according to claim 1, wherein the aluminum containing V/III semiconductor material is about 500 Å to about 5000 Å thick.

9. The VCSEL according to claim 1, wherein the aluminum containing V/III semiconductor material includes InAlAs.

10. The VCSEL according to claim 1, wherein the aluminum containing V/III semiconductor material includes at least one of AlGaAs, AlAsSb, AlGaP, AlInP, and AlInSb.

11. A method of fabricating a vertical cavity surface emitting laser (VCSEL), comprising:
providing an active region;
forming an aluminum containing current confinement layer over the active region;
forming a distributed Bragg reflector (DBR) over the active region; and
oxidizing a portion the current confinement layer to form a central aperture,
wherein forming the aluminum containing current confinement layer includes introducing, at a deposition temperature, group V-containing precursors and group III-containing precursors into a deposition chamber at a second flow rate, wherein a ratio of the first flow rate to the second flow rate is less than 25.

12. The method according to claim 11, wherein the deposition temperature is greater than about 600° C.

13. The method according to claim 11, wherein the deposition temperature is greater than about 650° C.

14. The method according to claim 11, wherein the deposition temperature is greater than about 700° C.

15. The method according to claim 11, wherein the a ratio of the first flow rate to the second flow rate is less than 10.

16. The method according to claim 11, wherein the a ratio of the first flow rate to the second flow rate is less than 5.

17. The method according to claim 11, wherein the a ratio of the first flow rate to the second flow rate is less than 1.

18. The method according to claim 11, wherein a thickness of the aluminum containing current confinement layer is about 500 Å to about 5000 Å.

19. The method according to claim 11, wherein the aluminum containing current confinement layer includes InAlAs.

20. The method according to claim 11, wherein the aluminum containing current confinement layer includes at least one of AlGaAs, AlAsSb, AlGaP, AlInP, and AlInSb.
